(19) United States
(12) Patent Application Publication
(10) Pub. No.: US 2019/0317408 A1
(43) Pub. Date: Oct. 17, 2019

(54) METHOD AND APPARATUS FOR PROCESSING SUBSTRATE

(71) Applicant: SEMES CO., LTD., Chungcheongnam-do (KR)

(72) Inventors: HEEJAE GOO, Cheonan-si (KR); KYO SANG YOON, Cheonan-si (KR); BYOUNGDOO CHOI, Seoul (KR); SANGMO YANG, Seoul (KR)

(21) Appl. No.: 16/380,785

(22) Filed: Apr. 10, 2019

(30) Foreign Application Priority Data
Apr. 16, 2018 (KR) 10-2018-0043806

(51) Int. Cl. G03F 7/16; H01L 21/027

(52) U.S. Cl. CPC G03F 7/168; H01L 21/0273

(57) ABSTRACT

The inventive concept relates to a substrate processing method and apparatus for providing a plurality of gas layers and contamination prevention liquid layers in a nozzle after the nozzle dispenses photoresist onto a substrate, thereby preventing photoresist in the nozzle from making contact with air and thus preventing the photoresist in the nozzle from being solidified by a reaction of the photoresist with air.

### CROSS-REFERENCE TO RELATED APPLICATIONS

A claim for priority under 35 U.S.C. § 119 is made to Korean Patent Application No. 10-2018-0043806 filed on Apr. 16, 2018, in the Korean Intellectual Property Office, the entire contents of which are hereby incorporated by reference.

### BACKGROUND

Embodiments of the inventive concept described herein relate to a substrate processing method and apparatus, and more particularly, relate to a substrate processing method and apparatus for preventing solidification of a processing liquid present in a nozzle.

A plurality of patterns have to be formed on a substrate, such as a semiconductor wafer, to manufacture a semiconductor device. The semiconductor patterns are formed by continuously performing various processes such as a depositing process, a lithography process, an etching process, and the like.

Among these processes, the lithography process includes a coating process of coating the substrate with a light-sensitive material such as photoresist to form a photoresist layer on the substrate, an exposing process of printing the pattern of a reticle on the photoresist layer of the substrate to form circuitry, and a developing process of dispensing a developing solution onto the photoresist layer of the substrate to selectively remove the exposed area or the opposite area.

A substrate processing apparatus for performing the coating process, among the aforementioned processes, has a processing unit, a home port, and a nozzle. The nozzle stands by in the home port while the processing unit does not perform a process on the substrate. The photoresist is usually solidified when making contact with air.

When the nozzle stands by in the home port, photoresist remaining in a discharge passage of the nozzle makes contact with air around the nozzle in the home port and is thus solidified in the nozzle.

In the case where the photoresist remaining in the discharge passage is solidified, the nozzle has to be removed from the apparatus, or has to be manually cleaned by a worker, to remove the solidified photoresist.

### SUMMARY

Embodiments of the inventive concept provide a substrate processing apparatus and method for preventing solidification of photoresist remaining in a nozzle while the nozzle stands by after completely dispensing photoresist.

The technical problems to be solved by the inventive concept are not limited to the aforementioned problems, and any other technical problems not mentioned herein will be clearly understood from the following description by those skilled in the art to which the inventive concept pertains.

According to an exemplary embodiment, a method for processing a substrate includes a process of processing the substrate by dispensing a processing liquid onto the substrate through a nozzle having a discharge passage formed therein and a storage process of storing the nozzle, with the processing liquid sucked back into the discharge passage. In the storage process, the nozzle is stored, with a first gas layer, a first contamination prevention liquid layer, a second gas layer, and a second contamination prevention liquid layer sequentially formed in the discharge passage, and the first gas layer is located adjacent to the processing liquid.

A third gas layer may be additionally formed between the second contamination prevention liquid layer and a distal end of the nozzle.

The processing liquid may be photoresist.

The first gas layer and the second gas layer may be air layers.

The first contamination prevention liquid layer and the second contamination prevention liquid layer may be thinner layers.

According to an exemplary embodiment, a method for processing a substrate includes a step of processing the substrate by dispensing a processing liquid onto the substrate through a nozzle, a first gas layer forming step of forming a first gas layer in a distal end of a discharge passage of the nozzle by sucking back the processing liquid in the discharge passage of the nozzle, a first liquid layer forming step of forming a first contamination prevention liquid layer in the discharge passage of the nozzle by pulling a first contamination prevention liquid into the discharge passage of the nozzle from the outside by applying a suction force to the discharge passage of the nozzle, after the first gas layer forming step, a second gas layer forming step of forming a second gas layer in the discharge passage of the nozzle by applying a suction force to the passage of the nozzle, after the first liquid layer forming step, and a second liquid layer forming step of forming a second contamination prevention liquid layer in the discharge passage of the nozzle by pulling a second contamination prevention liquid into the discharge passage of the nozzle from the outside by applying a suction force to the discharge passage of the nozzle, after the second gas layer forming step.

The method may further include a third gas layer forming step of forming a third gas layer in the discharge passage of the nozzle by applying a suction force to the passage of the nozzle, after the second liquid layer forming step.

The processing liquid may be photoresist.

The first gas layer and the second gas layer may be air layers.

The first contamination prevention liquid and the second contamination prevention liquid may be thinner.

The first liquid layer forming step and the second liquid layer forming step may be performed, with a predetermined level of liquid in a home port in which the nozzle stands by and a discharge end of the nozzle submerged in the liquid. The first gas layer forming step and the second gas layer forming step may be performed, with the discharge end of the nozzle located above a surface of the liquid in the home port in which the nozzle stands by.

The first gas layer forming step may be performed in a processing space in which the processing liquid is dispensed onto the substrate to process the substrate.

According to an exemplary embodiment, an apparatus for processing a substrate includes a cup having a processing space in which the substrate is processed, a support unit that supports the substrate in the processing space, a liquid dispensing unit that dispenses a processing liquid onto the substrate supported on the support unit, a home port that stores a nozzle of the liquid dispensing unit while the nozzle does not dispense the processing liquid onto the substrate, and a controller that controls the liquid dispensing unit. The liquid dispensing unit includes the nozzle having a discharge passage formed therein, a liquid supply tube that supplies the processing liquid into the nozzle, and a suck-back valve that is installed on the liquid supply tube and that applies a suction force to the discharge passage. The controller controls the suck-back valve to apply the suction force to the discharge passage of the nozzle to sequentially form a first gas layer, a first contamination prevention liquid layer, a second gas layer, and a second contamination prevention liquid layer in the nozzle while the nozzle is stored in the home port, and the first gas layer is located adjacent to the processing liquid.

The controller may control the liquid dispensing unit to form the first gas layer while the nozzle is located in or above the processing space.

The controller may control the liquid dispensing unit to form the first contamination prevention liquid layer, the second gas layer, and the second contamination prevention liquid layer in the discharge passage, with the nozzle located in the home port.

The controller may apply a suction force to the discharge passage of the nozzle to form a third gas layer between the second contamination prevention liquid layer and a discharge opening of the nozzle.

The first gas layer, the second gas layer, and the third gas layer may be air layers, and the first contamination prevention liquid layer and the second contamination prevention liquid layer may be thinner layers.

The home port may include a body having a space in which the nozzle is received, a supply line that supplies a contamination prevention liquid into the body, and a drain line that drains the contamination prevention liquid from the body.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a top view illustrating substrate processing equipment according to an embodiment of the inventive concept;

FIG. 2 is a view illustrating the substrate processing equipment of FIG. 1 when viewed in direction A-A;

FIG. 3 is a view illustrating the substrate processing equipment of FIG. 1 when viewed in direction B-B;

FIG. 4 is a view illustrating the substrate processing equipment of FIG. 1 when viewed in direction C-C;

FIGS. 5 and 6 are a sectional view and a plan view illustrating a substrate processing apparatus provided in a coating chamber of FIG. 1;

FIG. 7 is a flowchart illustrating a substrate processing method according to an embodiment of the inventive concept; and

FIGS. 8 to 12 are exemplary views illustrating states in which a substrate is processed according to the flowchart of FIG. 7.

### DETAILED DESCRIPTION

Hereinafter, embodiments of the inventive concept will be described in more detail with reference to the accompanying drawings. The inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. In the drawings, the dimensions of components are exaggerated for clarity of illustration.

Substrate processing equipment of the inventive concept may be used to perform a photolithography process on substrates such as semiconductor wafers or flat display panels. According to an embodiment, the substrate processing equipment of the inventive concept may be an apparatus that is connected to an exposure apparatus and performs a coating process and a developing process on substrates. In the following description, it will be exemplified that wafers are used as the substrates.

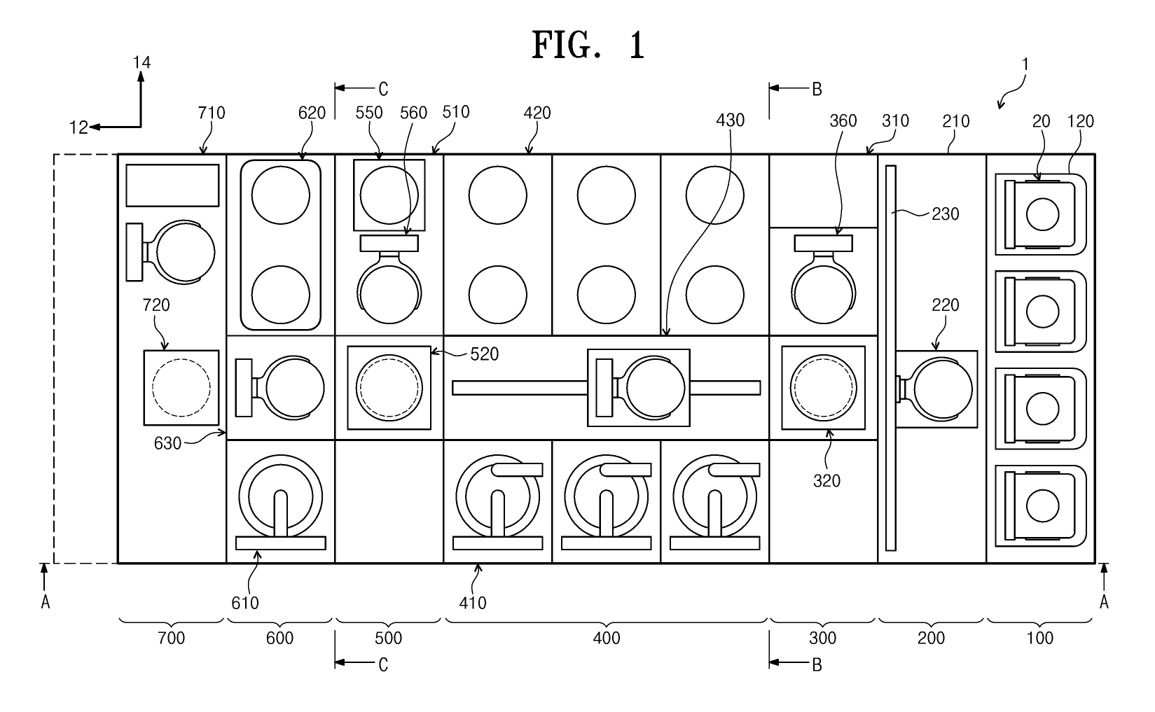

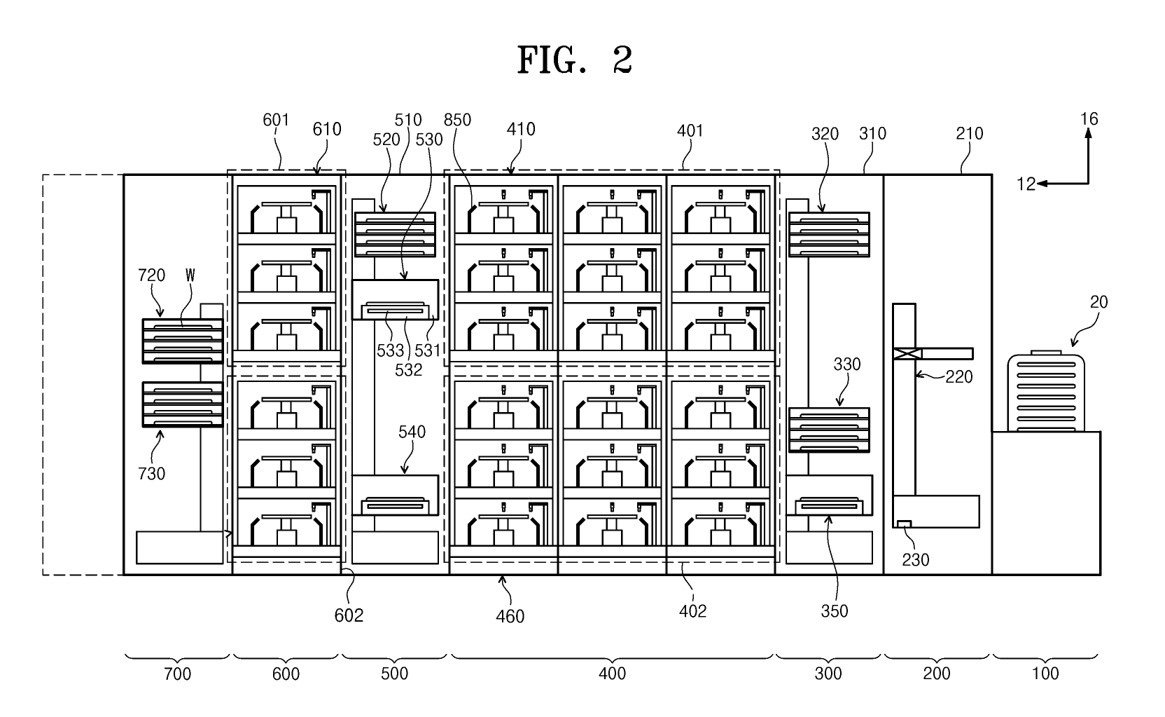

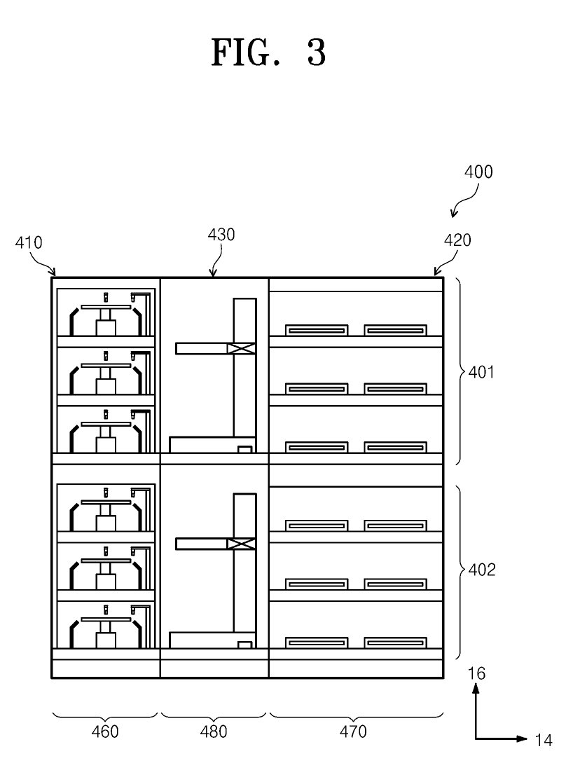

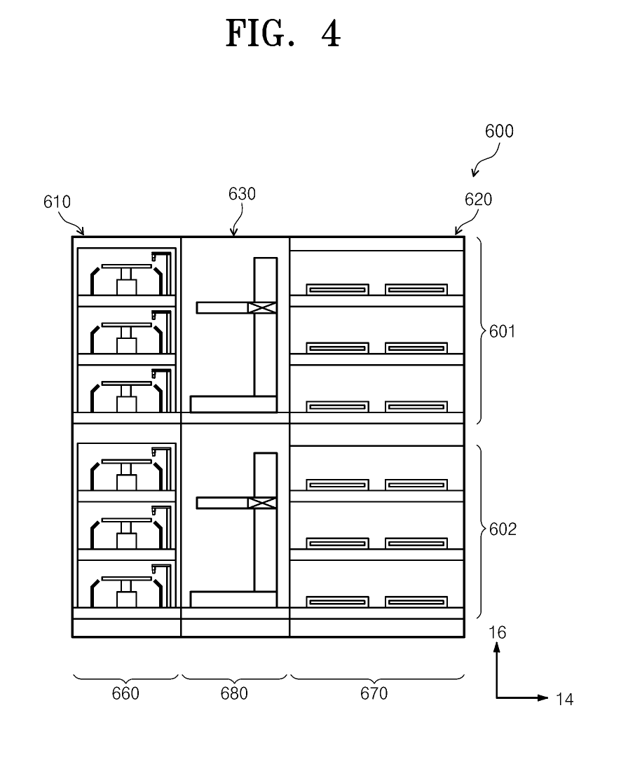

FIGS. 1 to 4 are schematic views illustrating substrate processing equipment 1 according to an embodiment of the inventive concept. FIG. 1 is a top view illustrating the substrate processing equipment 1. FIG. 2 is a view illustrating the substrate processing equipment 1 of FIG. 1 when viewed in direction A-A. FIG. 3 is a view illustrating the substrate processing equipment 1 of FIG. 1 when viewed in direction B-B. FIG. 4 is a view illustrating the substrate processing equipment 1 of FIG. 1 when viewed in direction C-C.

Referring to FIGS. 1 to 4, the substrate processing equipment 1 includes a load port 100, an index module 200, a first buffer module 300, a coating and developing module 400, a second buffer module 500, a pre/post-exposure processing module 600, and an interface module 700.

Hereinafter, a first direction 12 refers to the direction in which the load port 100, the index module 200, the first buffer module 300, the coating and developing module 400, the second buffer module 500, the pre/post-exposure processing module 600, and the interface module 700 are arranged. A second direction 14 refers to a direction that is perpendicular to the first direction 12 when viewed from above, and a third direction 16 refers to a direction that is perpendicular to the first direction 12 and the second direction 14.

Cassettes 20 having substrates W received therein are placed on mounting tables 120. The cassettes 20 have an airtight structure. For example, front open unified pods (FOUPs) having a door at the front thereof may be used as the cassettes 20.

Hereinafter, the load port 100, the index module 200, the first buffer module 300, the coating and developing module 400, the second buffer module 500, the pre/post-exposure processing module 600, and the interface module 700 will be described in detail.

The load port 100 has the mounting tables 120 on which the cassettes 20 having the substrates W received therein are placed. The mounting tables 120 are arranged in a row along the second direction 14. FIG. 1 illustrates an example that four mounting tables 120 are arranged in a row.

The index module 200 transfers the substrates W between the cassettes 20 placed on the mounting tables 120 of the load port 100 and the first buffer module 300. The index module 200 has a frame 210, an index robot 220, and a guide rail 230. The frame 210 has a rectangular parallelepiped shape with an empty space inside and is disposed between the load port 100 and the first buffer module 300.

The first buffer module 300 has a frame 310, a first buffer 320, a second buffer 330, a cooling chamber 350, and a first buffer robot 360. The frame 310 has a rectangular parallelepiped shape with an empty space inside and is disposed between the index module 200 and the coating and developing module 400. The first buffer 320, the second buffer 330, the cooling chamber 350, and the first buffer robot 360 are located in the frame 310. The first buffer 320 and the second buffer 330 temporarily store the substrates W. The first buffer robot 360 transfers the substrates W between the first buffer 320 and the second buffer 330. The cooling chamber 350 cools the substrates W.

The coating and developing module 400 performs a process of coating the substrates W with photoresist before an exposing process and performs a developing process on the substrates W after the exposing process. The coating and developing module 400 has a rectangular parallelepiped shape. The coating and developing module 400 has a coating module 401 and a developing module 402.

The coating module 401 and the developing module 402 are disposed on different floors. According to an embodiment, the coating module 401 is located over the developing module 402.

The coating module 401 performs a process of coating the substrates W with a light-sensitive material such as photoresist and a heat treatment process of heating or cooling the substrates W before and after the process of coating the substrates W with the photoresist.

The coating module 401 has photoresist coating chambers 410, bake chambers 420, and a transfer chamber 430. The photoresist coating chambers 410, the transfer chamber 430, and the bake chambers 420 are sequentially arranged along the second direction 14. Accordingly, the photoresist coating chambers 410 and the bake chambers 420 are spaced apart from each other in the second direction 14, with the transfer chamber 430 therebetween.

The photoresist coating chambers 410 are arranged in the first direction 12 and the third direction 16. The drawings illustrate an example that six photoresist coating chambers 410 are arranged.

The bake chambers 420 perform heat treatment on the substrates W. For example, the bake chambers 420 perform a prebake process of removing organics or moisture on the surfaces of the substrates W by heating the substrates W to a predetermined temperature before coating the substrates W with the photoresist, or perform a soft bake process after coating the substrates W with the photoresist. In addition, the bake chambers 420 perform a cooling process of cooling the substrates W after the heating processes.

The transfer chamber 430 is located side by side with the first buffer 320 of the first buffer module 300 in the first direction 12.

The developing module 402 performs a developing process of removing part of the photoresist by dispensing a developing solution to obtain patterns on the substrates W and a heat treatment process of heating or cooling the substrates W before or after the developing process. The developing module 402 has developing chambers 460, bake chambers 470, and a transfer chamber 480. The developing chambers 460, the transfer chamber 480, and the bake chambers 470 are sequentially arranged along the second direction 14.

The developing chambers 460 all have the same structure. However, the types of developing solutions used in the respective developing chambers 460 may differ from each other. The developing chambers 460 remove light-exposed regions of the photoresist on the substrates W. At this time, light-exposed regions of a protective film are also removed. Alternatively, depending on the type of photoresist used, only masked regions of the photoresist and the protective film may be removed.

The bake chambers 470 of the developing module 402 perform heat treatment on the substrates W. For example, the bake chambers 470 perform a post bake process of heating the substrates W before the developing process, a hard bake process of heating the substrates W after the developing process, and a cooling process of cooling the substrates W after the bake processes.

The second buffer module 500 serves as a passage through which the substrates W are carried between the coating and developing module 400 and the pre/post-exposure processing module 600. In addition, the second buffer module 500 performs a predetermined process, such as a cooling process or an edge exposing process, on the substrates W. The second buffer module 500 has a frame 510, a buffer 520, a first cooling chamber 530, a second cooling chamber 540, an edge exposing chamber 550, and a second buffer robot 560.

In the case where a stepper performs liquid immersion lithography, the pre/post-exposure processing module 600 may perform a process of applying protective films that protect the photoresist films on the substrates W during the liquid immersion lithography. Furthermore, the pre/post-exposure processing module 600 may perform a process of cleaning the substrates W after the exposing process. In addition, in the case where a coating process is performed using a chemically amplified resist, the pre/post-exposure processing module 600 may perform a post-exposure bake process.

The pre/post-exposure processing module 600 has a pre-processing module 601 and a post-processing module 602. The pre-processing module 601 performs a process of processing the substrates W before the exposing process, and the post-processing module 602 performs a process of processing the substrates W after the exposing process.

In the pre/post-exposure processing module 600, the pre-processing module 601 and the post-processing module 602 are completely separated from each other.

The coating module 601 has protective-film coating chambers 610, bake chambers 620, and a transfer chamber 630. The protective-film coating chambers 610, the transfer chamber 630, and the bake chambers 620 are sequentially arranged along the second direction 14.

Accordingly, the protective-film coating chambers 610 and the bake chambers 620 are spaced apart from each other in the second direction 14, with the transfer chamber 630 therebetween. The protective-film coating chambers 610 are vertically arranged along the third direction 16.

Alternatively, the protective-film coating chambers 610 may be arranged in the first direction 12 and the third direction 16. The bake chambers 620 are vertically arranged along the third direction 16. Alternatively, the bake chambers 620 may be arranged in the first direction 12 and the third direction 16.

The post-processing module 620 has cleaning chambers 660, post-exposure bake chambers 670, and a transfer chamber 680. The cleaning chambers 660, the transfer chamber 680, and the post-exposure bake chambers 670 are sequentially arranged along the second direction 14.

Accordingly, the cleaning chambers 660 and the post-exposure bake chambers 670 are spaced apart from each other in the second direction 14, with the transfer chamber 680 therebetween. The cleaning chambers 660 may be vertically arranged along the third direction 16.

Alternatively, the cleaning chambers 660 may be arranged in the first direction 12 and the third direction 16. The post-exposure bake chambers 670 may be vertically arranged along the third direction 16. Alternatively, the post-exposure bake chambers 670 may be arranged in the first direction 12 and the third direction 16.

The interface module 700 transfers the substrates W between the pre-processing module 601 and the post-processing module 602. The interface module 700 has a frame 710, a first buffer 720, a second buffer 730, and an interface robot 740. The first buffer 720, the second buffer 730, and the interface robot 740 are located in the frame 710.

The first buffer 720 and the second buffer 730 are vertically spaced apart from each other by a predetermined distance. The first buffer 720 is disposed in a higher position than the second buffer 730. The first buffer 720 is located at the height corresponding to the pre-processing module 601, and the second buffer 730 is disposed at the height corresponding to the post-processing module 602. When viewed from above, the first buffer 720 is aligned with the transfer chamber 630 of the pre-processing module 601 along the first direction 12, and the second buffer 730 is aligned with the transfer chamber 680 of the post-processing module 602 along the first direction 12.

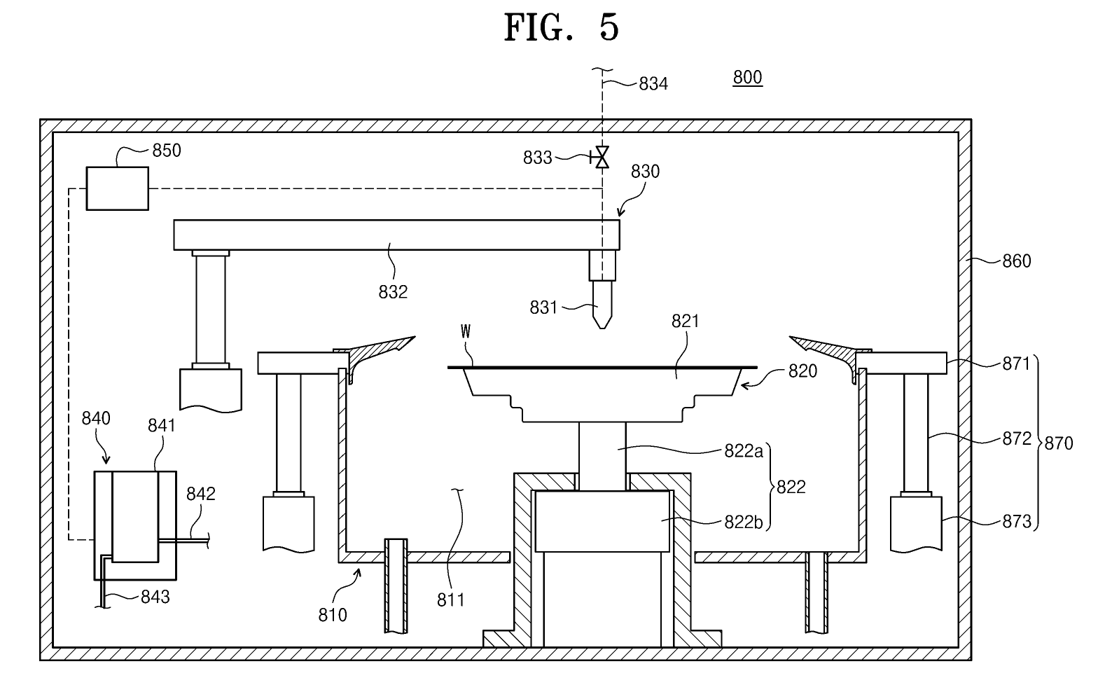

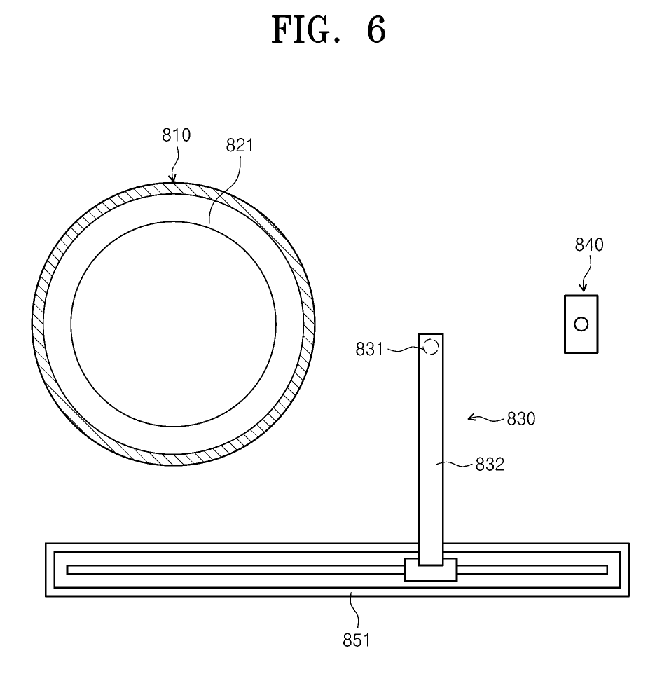

FIGS. 5 and 6 are a sectional view and a plan view illustrating an example of the photoresist coating chambers of FIG. 1. A photoresist coating chamber 800 includes a cup 810, a support unit 820, a liquid dispensing unit 830, a home port 840, a controller 850, and a housing 860.

The cup 810 has a processing space 811 therein, in which a substrate W is processed. The processing space 811 is open at the top. According to an embodiment, a lifting unit 870 is provided on a side of the cup 810. The lifting unit 870 vertically moves the cup 810. The lifting unit 870 includes a bracket 871, a movable shaft 872, and an actuator 873. The bracket 871 is fixedly attached to the cup 810. The movable shaft 872 is fixedly coupled to the bracket 871 and vertically moved by the actuator 873.

The support unit 820 supports and rotates the substrate W in the processing space 811. The support unit 820 includes a support plate 821 and a drive member 822. The substrate W is placed on the top side of the support plate 821. The support plate 821 clamps the substrate W by vacuum pressure to prevent the substrate W from being separated from the support plate 821 when the support plate 821 is rotated. The support plate 821 may have a smaller area than the substrate W.

The support plate 821 is rotated by the drive member 822. The drive member 822 is coupled to the bottom side of the support plate 821. The drive member 822 includes a drive shaft 822a and an actuator 822b. The drive shaft 822a is coupled to the bottom side of the support plate 821.

The liquid dispensing unit 830 dispenses photoresist onto the substrate W placed on the support unit 820. The liquid dispensing unit 830 includes a nozzle 831, a support rod 832, a suck-back valve 833, and a liquid supply line 834.

The nozzle 831 dispenses the photoresist onto the substrate W. The nozzle 831 has a discharge passage formed therein, through which the photoresist flows. The nozzle 831 is fixedly coupled to the distal end of the support rod 832. The photoresist is supplied into the nozzle 831 through the liquid supply line 834. The suck-back valve 833 is installed on the liquid supply line 834. The suck-back valve 833 applies a suction force to the discharge passage of the nozzle 831. The home port 840 serves as a standby space in which the nozzle 831 stands by and is stored while a coating process is not performed.

The home port 840 includes a body 841, a supply line 842, and a drain line 843. The body 841 provides a space in which the nozzle 831 is received. The body 841 has an inner space that is open at the top.

The supply line 842 is connected to the body 841 to supply thinner into the inner space of the body 841. The drain line 843 is connected to the body 841 to drain the thinner from the inner space of the body 841. Valves are installed on the supply line 842 and the drain line 843, respectively.

The controller 850 controls the liquid dispensing unit 830 and the home port 840. The housing 860 forms the external appearance of the photoresist coating chamber 800. The cup 810, the support unit 820, the liquid dispensing unit 830, and the home port 840 are located inside the housing 860. The controller 850 is located outside the housing 860.

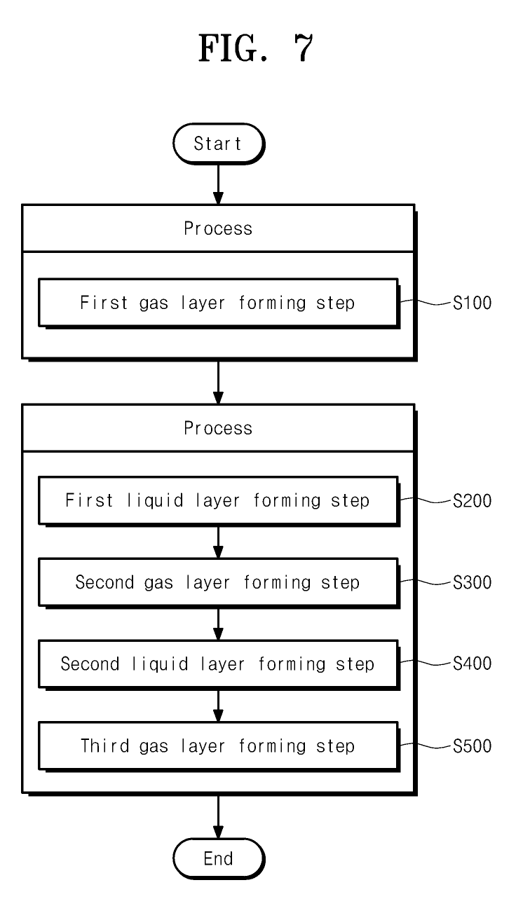

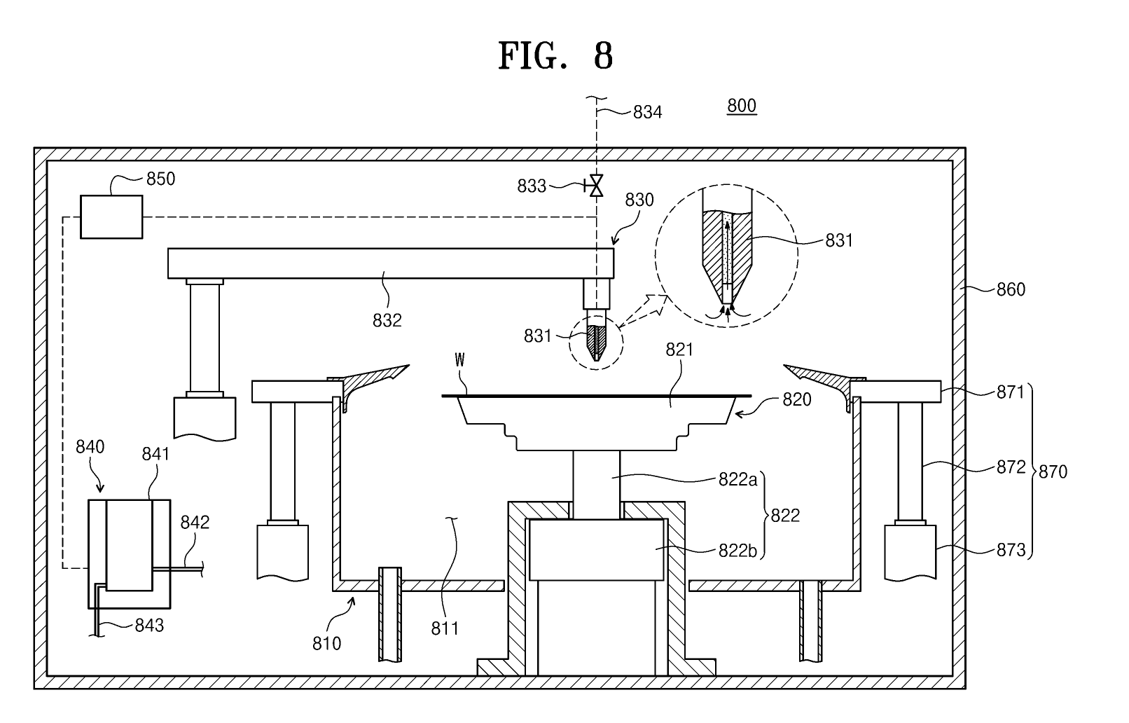

FIG. 7 is a flowchart illustrating a substrate processing method according to an embodiment of the inventive concept. FIGS. 8 to 12 are views sequentially illustrating a method for storing the nozzle 831 in a standby state.

Hereinafter, a method for controlling the liquid dispensing unit 830 and the home port 840 by the controller 850 will be described with reference to FIGS. 8 to 12. After the substrate W is coated with photoresist dispensed by the nozzle 831, first gas layer forming step S100, first liquid layer forming step S200, second gas layer forming step S300, second liquid layer forming step S400, and third gas layer forming step S500 are performed in a serial order.

According to an embodiment, first gas layer forming step S100 is performed before the nozzle 831 is moved to the home port 840. For example, first gas layer forming step S100 is performed while the nozzle 831 is located in the processing space 811 or directly above the processing space 811. Referring to FIG. 8, in first gas layer forming step S100, the suck-back valve 833 applies a suction force to the discharge passage of the nozzle 831. Accordingly, the photoresist remaining in the discharge passage of the nozzle 831 is sucked back by a predetermined distance in the discharge passage, and air around the nozzle 831 is pulled into the distal end of the discharge passage to form a first gas layer G1. Because the photoresist is sucked back by the predetermined distance in the discharge passage, the photoresist is prevented from dropping from the nozzle 831 while the nozzle 831 is being moved.

When first gas layer forming step S100 is completed, the nozzle 831 is moved to the home port 840 and inserted into the inner space of the home port 840. A storage process of sucking back the photoresist in the nozzle 831 a plurality of times by operating the suck-back valve 833 is performed in the home port 840.

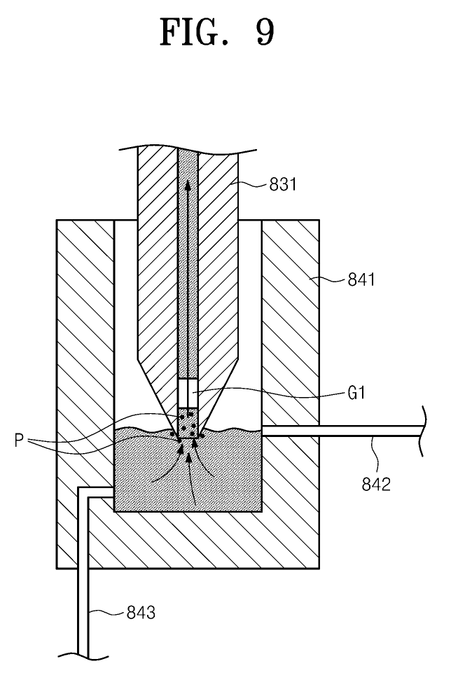

Next, first liquid layer forming step S200 is performed. Referring to FIG. 9, in first liquid layer forming step S200, a predetermined amount of thinner is supplied into the inner space of the body 841 through the supply line 842. The nozzle 831 is located such that the discharge opening thereof is submerged in the thinner.

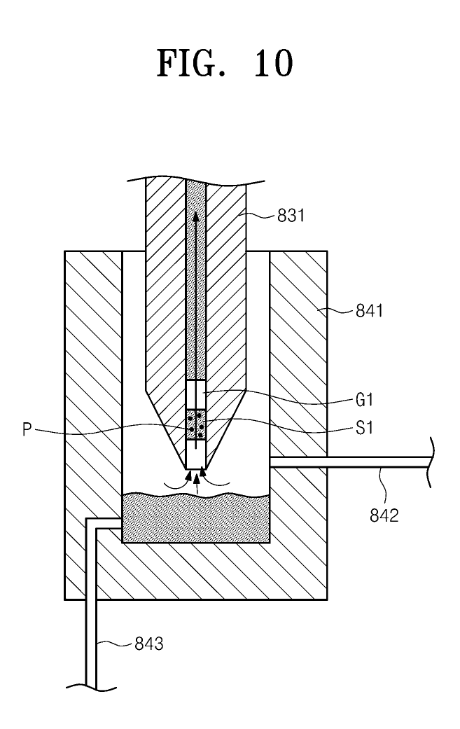

The suck-back valve 833 applies a suction force to the discharge passage of the nozzle 831. Accordingly, the photoresist and the first gas layer G1 are sucked back by a predetermined distance in the discharge passage, and a predetermined amount of thinner is pulled into the discharge opening of the nozzle 831 to form a first contamination prevention liquid layer S1. Thereafter, second gas layer forming step S300 is performed. Referring to FIG. 10, the nozzle 831 is located such that the discharge opening thereof is above the surface of the thinner. To this end, the nozzle 831 may be spaced a predetermined distance apart upward from the surface of the thinner, or a predetermined amount of thinner may be drained from the body 841 through the drain line 843.

The suck-back valve 833 applies a suction force to the discharge passage of the nozzle 831. Accordingly, the photoresist, the first gas layer G1, and the first contamination prevention liquid layer S1 are sucked back by a predetermined distance in the discharge passage, and a predetermined amount of air around the nozzle 831 is pulled into the discharge opening of the nozzle 831 to form a second gas layer G2.

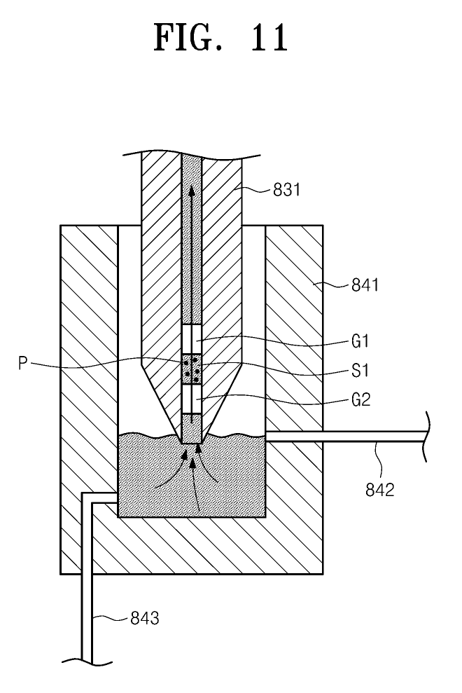

After that, second liquid layer forming step S400 is performed. Referring to FIG. 11, in second liquid layer forming step S400, the nozzle 831 is located such that the discharge opening thereof is submerged in the thinner. To this end, the nozzle 831 may be moved downward by a predetermined distance, or a predetermined amount of thinner may be supplied into the inner space of the body 841.

The suck-back valve 833 applies a suction force to the discharge passage of the nozzle 831. Accordingly, the photoresist, the first gas layer G1, the first contamination prevention liquid layer S1, and the second gas layer G2 are sucked back by a predetermined distance in the discharge passage, and a predetermined amount of thinner is pulled into the discharge opening of the nozzle 831 to form a second contamination prevention liquid layer S2.

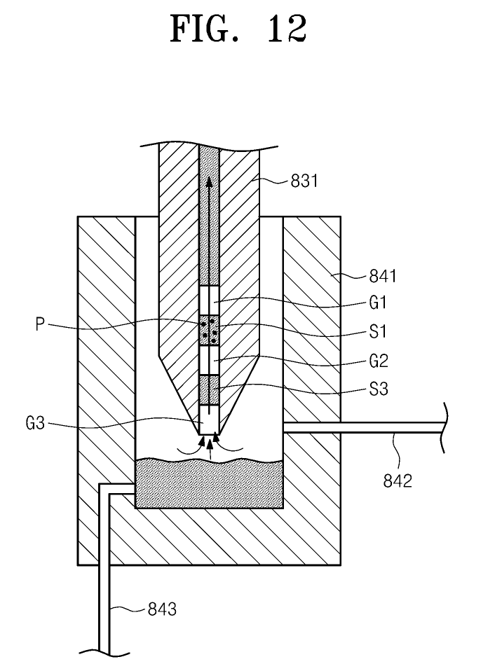

Finally, third gas layer forming step S500 is performed. Referring to FIG. 12, the nozzle 831 is located such that the discharge opening thereof is above the surface of the thinner. To this end, the nozzle 831 may be spaced a predetermined distance apart upward from the surface of the thinner, or a predetermined amount of thinner may be drained from the body 841 through the drain line 843.

The suck-back valve 833 applies a suction force to the discharge passage of the nozzle 831. Accordingly, the photoresist, the first gas layer G1, the first contamination prevention liquid layer S1, the second gas layer G2, and the second contamination prevention liquid layer S2 are sucked back by a predetermined distance in the discharge passage, and a predetermined amount of air around the nozzle 831 is pulled into the discharge opening of the nozzle 831 to form a third gas layer G3.

According to the embodiment of the inventive concept, the plurality of contamination prevention liquid layers S1 and S2 are provided in the nozzle 831, and thus the following effects are achieved.

In general, the photoresist is solidified when making contact with air. While the photoresist is dispensed onto the substrate W, the photoresist is partly deposited around the discharge opening of the nozzle 831. When the thinner is pulled into the nozzle 831 to form the first contamination prevention liquid layer S1 while the nozzle 831 is stored after the completion of the process, the photoresist deposited around the discharge opening of the nozzle 831 is dissolved in the thinner and pulled into the discharge passage in the nozzle 831, along with the thinner.

Therefore, the dissolved photoresist in the first contamination prevention liquid layer S1 is solidified when the first contamination prevention liquid layer S1 is exposed to air outside the nozzle 831. However, in the case where the second contamination prevention liquid layer S2 is additionally formed as in the embodiment of the inventive concept, no photoresist is contained in the second contamination prevention liquid layer S2, or only a very small amount of photoresist is dissolved in the second contamination prevention liquid layer S2, because most of the photoresist deposited around the discharge opening of the nozzle 831 is removed when the thinner is pulled into the nozzle 831 to form the first contamination prevention liquid layer S1.

Accordingly, the above-described problem that the photoresist is solidified in the second contamination prevention liquid layer S2 does no arise even though the second contamination prevention liquid layer S2 is exposed to air outside the nozzle 831.

Although it has been exemplified that the liquid intake step is performed twice, more liquid intake steps may be performed according to the degree to which the distal end of the nozzle 831 is contaminated by the photoresist.

The above detailed description is based on the substrate processing apparatus according to the embodiment of the inventive concept. However, without being limited thereto, the inventive concept is applicable to all apparatuses for processing a substrate.

Furthermore, although it has been exemplified that the first gas layer G1, the second gas layer G2, and the third gas layer G3 are air layers and the first contamination prevention liquid layer S1 and the second contamination prevention liquid layer S2 are thinner layers, the inventive concept is not limited thereto.

Moreover, although it has been exemplified that the formation of the first gas layer G1 is performed in the processing space 811 or directly above the processing space 811, the inventive concept is not limited thereto.

In addition, although it has been exemplified that the third gas layer G3 is formed under the second contamination prevention liquid layer S2 through third gas layer forming step S500, third gas layer forming step S500 may not be performed, and the third gas layer G3 may not be provided.

According to the embodiments of the inventive concept, the substrate processing apparatus and method provides the plurality of gas layers and contamination prevention liquid layers in the nozzle, thereby blocking a flow of air toward the photoresist in the nozzle and preventing the photoresist from being consistently exposed to a reactant contained in air, which in turn prevents solidification of the photoresist.

Especially, the last contamination prevention liquid layer, among the plurality of contamination prevention liquid layers, contains a relatively very small amount of photoresist and is hence prevented from being solidified even though making contact with air.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A method for processing a substrate, the method comprising:
a process of processing the substrate by dispensing a processing liquid onto the substrate through a nozzle having a discharge passage formed therein; and
a storage process of storing the nozzle, with the processing liquid sucked back into the discharge passage,
wherein in the storage process, the nozzle is stored, with a first gas layer, a first contamination prevention liquid layer, a second gas layer, and a second contamination prevention liquid layer sequentially formed in the discharge passage, and
wherein the first gas layer is located adjacent to the processing liquid.

2. The method of claim 1, wherein a third gas layer is additionally formed between the second contamination prevention liquid layer and an end of the nozzle.

3. The method of claim 1, wherein the processing liquid is photoresist.

4. The method of claim 3, wherein the first gas layer and the second gas layer are air layers.

5. The method of claim 3, wherein the first contamination prevention liquid layer and the second contamination prevention liquid layer are thinner layers.

6. A method for processing a substrate, the method comprising:
a step of processing the substrate by dispensing a processing liquid onto the substrate through a nozzle;
a first gas layer forming step of forming a first gas layer in an end of a discharge passage of the nozzle by sucking back the processing liquid in the discharge passage of the nozzle;
a first liquid layer forming step of forming a first contamination prevention liquid layer in the discharge passage of the nozzle by pulling a first contamination prevention liquid into the discharge passage of the nozzle from the outside by applying a suction force to the discharge passage of the nozzle, after the first gas layer forming step;
a second gas layer forming step of forming a second gas layer in the discharge passage of the nozzle by applying a suction force to the passage of the nozzle, after the first liquid layer forming step; and
a second liquid layer forming step of forming a second contamination prevention liquid layer in the discharge passage of the nozzle by pulling a second contamination prevention liquid into the discharge passage of the nozzle from the outside by applying a suction force to the discharge passage of the nozzle, after the second gas layer forming step.

7. The method of claim 6, further comprising:
a third gas layer forming step of forming a third gas layer in the discharge passage of the nozzle by applying a suction force to the passage of the nozzle, after the second liquid layer forming step.

8. The method of claim 6, wherein the processing liquid is photoresist.

9. The method of claim 8, wherein the first gas layer and the second gas layer are air.

10. The method of claim 6, wherein the first contamination prevention liquid and the second contamination prevention liquid are thinner.

11. The method of claim 6, wherein each of the first liquid layer forming step and the second liquid layer forming step is performed, with a predetermined level of liquid in a home port in which the nozzle stands by and a discharge end of the nozzle submerged in the liquid, and
wherein each of the first gas layer forming step and the second gas layer forming step is performed, with the discharge end of the nozzle located above a surface of the liquid in the home port in which the nozzle stands by.

12. The method of claim 11, wherein the first gas layer forming step is performed in a processing space in which the processing liquid is dispensed onto the substrate to process the substrate.

13. An apparatus for processing a substrate, the apparatus comprising:
a cup having a processing space therein, in which the substrate is processed;
a support unit configured to support the substrate in the processing space;
a liquid dispensing unit including a nozzle configured to dispense a processing liquid onto the substrate supported on the support unit;
a home port configured to store the nozzle while the nozzle does not dispense the processing liquid onto the substrate; and
a controller configured to control the liquid dispensing unit,
wherein the liquid dispensing unit includes:
the nozzle having a discharge passage formed therein;
a liquid supply tube configured to supply the processing liquid into the nozzle; and
a suck-back valve installed on the liquid supply tube and configured to apply a suction force to the discharge passage,
wherein the controller controls the suck-back valve to apply the suction force to the discharge passage of the nozzle to sequentially form a first gas layer, a first contamination prevention liquid layer, a second gas layer, and a second contamination prevention liquid layer in the nozzle while the nozzle is stored in the home port, and
wherein the first gas layer is located adjacent to the processing liquid.

14. The apparatus of claim 13, wherein the controller controls the liquid dispensing unit to form the first gas layer while the nozzle is located in or above the processing space.

15. The apparatus of claim 13, wherein the controller controls the liquid dispensing unit to form the first contamination prevention liquid layer, the second gas layer, and the second contamination prevention liquid layer in the discharge passage, with the nozzle located in the home port.

16. The apparatus of claim 13, wherein the controller applies a suction force to the discharge passage of the nozzle to form a third gas layer between the second contamination prevention liquid layer and a discharge opening of the nozzle.

17. The apparatus of claim 13, wherein the first gas layer, the second gas layer, and the third gas layer are air, and
wherein the first contamination prevention liquid layer and the second contamination prevention liquid layer are thinner.

18. The apparatus of claim 13, wherein the home port includes:
a body having a space in which the nozzle is received;
a supply line configured to supply a contamination prevention liquid into the body; and
a drain line configured to drain the contamination prevention liquid from the body.
